(19) United States
(12) Patent Application Publication
(10) Pub. No.: US 2026/0282387 A1
(43) Pub. Date: Sep. 17, 2026

(54) MAGNETIC MEMORY DEVICE

(71) Applicant: Kioxia Corporation, Tokyo (JP)

(72) Inventor: Yuichi ITO, Seoul (KR)

(73) Assignee: Kioxia Corporation, Tokyo (JP)

(21) Appl. No.: 19/325,153

(22) Filed: Sep. 10, 2025

(30) Foreign Application Priority Data
Mar. 17, 2025 (JP) 2025-042276

(51) Int. Cl. H10B 61/00; H10N 50/01; H10N 50/10

(52) U.S. Cl. CPC H10B 61/10; H10N 50/01; H10N 50/10

(57) ABSTRACT

According to one embodiment, a magnetic memory device includes a plurality of magnetoresistance effect elements arranged along first and second directions, and an insulating layer including hole portions provided for magnetoresistance effect elements. The magnetoresistance effect element includes first and second magnetic layers and first non-magnetic layer between the first and second magnetic layers, each of the second magnetic layer and the first non-magnetic layer includes a portion provided along bottom and side surfaces of a corresponding hole portion, and the portion of the second magnetic layer along the bottom and side surfaces has magnetism, and at least a portion of the second magnetic layer along the bottom surface has a variable magnetization direction.

### CROSS-REFERENCE TO RELATED APPLICATIONS

This application is based upon and claims the benefit of priority from Japanese Patent Application No. 2025-042276, filed Mar. 17, 2025, the entire contents of which are incorporated herein by reference.

### FIELD

Embodiments described herein relate generally to a magnetic memory device.

### BACKGROUND

Magnetic memory devices in which a plurality of memory cells each including a magnetoresistance effect element integrated on a semiconductor substrate, have been proposed.

### BRIEF DESCRIPTION OF THE DRAWINGS

FIG. 1 is a perspective view schematically showing a basic configuration of a magnetic memory device according to an embodiment.

FIG. 2A is a cross-sectional view schematically showing a specific configuration of the magnetic memory device according to the embodiment.

FIG. 2B is a cross-sectional view schematically showing the specific configuration of the magnetic memory device according to the embodiment.

FIG. 3A is a cross-sectional view schematically showing a part of a method of manufacturing the magnetic memory device according to the embodiment.

FIG. 3B is a cross-sectional view schematically showing a part of the method of manufacturing the magnetic memory device according to the embodiment.

FIG. 4A is a cross-sectional view schematically showing a part of the method of manufacturing the magnetic memory device according to the embodiment.

FIG. 4B is a cross-sectional view schematically showing a part of the method of manufacturing the magnetic memory device according to the embodiment.

FIG. 5A is a cross-sectional view schematically showing a part of the method of manufacturing the magnetic memory device according to the embodiment.

FIG. 5B is a cross-sectional view schematically showing a part of the method of manufacturing the magnetic memory device according to the embodiment.

FIG. 6A is a cross-sectional view schematically showing a part of the method of manufacturing the magnetic memory device according to the embodiment.

FIG. 6B is a cross-sectional view schematically showing a part of the method of manufacturing the magnetic memory device according to the embodiment.

FIG. 7A is a cross-sectional view schematically showing a part of the method of manufacturing the magnetic memory device according to the embodiment.

FIG. 7B is a cross-sectional view schematically showing a part of the method of manufacturing the magnetic memory device according to the embodiment.

FIG. 8A is a cross-sectional view schematically showing a part of the method of manufacturing the magnetic memory device according to the embodiment.

FIG. 8B is a cross-sectional view schematically showing a part of the method of manufacturing the magnetic memory device according to the embodiment.

FIG. 9A is a cross-sectional view schematically showing a part of the method of manufacturing the magnetic memory device according to the embodiment.

FIG. 9B is a cross-sectional view schematically showing a part of the method of manufacturing the magnetic memory device according to the embodiment.

FIG. 10A is a cross-sectional view schematically showing a part of the method of manufacturing the magnetic memory device according to the embodiment.

FIG. 10B is a cross-sectional view schematically showing a part of the method of manufacturing the magnetic memory device according to the embodiment.

FIG. 11A is a cross-sectional view schematically showing a part of the method of manufacturing the magnetic memory device according to the embodiment.

FIG. 11B is a cross-sectional view schematically showing a part of the method of manufacturing the magnetic memory device according to the embodiment.

FIG. 12A is a cross-sectional view schematically showing a part of the method of manufacturing the magnetic memory device according to the embodiment.

FIG. 12B is a cross-sectional view schematically showing a part of the method of manufacturing the magnetic memory device according to the embodiment.

FIG. 13A is a cross-sectional view schematically showing a part of the method of manufacturing the magnetic memory device according to the embodiment.

FIG. 13B is a cross-sectional view schematically showing a part of the method of manufacturing the magnetic memory device according to the embodiment.

FIG. 14A is a cross-sectional view schematically showing a specific configuration of a magnetic memory device according to a first modified example of the embodiment.

FIG. 14B is a cross-sectional view schematically showing the specific configuration of the magnetic memory device according to the first modified example of the embodiment.

FIG. 15A is a cross-sectional view schematically showing a specific configuration of a magnetic memory device according to a second modified example of the embodiment.

FIG. 15B is a cross-sectional view schematically showing the specific configuration of the magnetic memory device according to the second modified example of the embodiment.

### DETAILED DESCRIPTION

In general, according to one embodiment, a magnetic memory device includes a plurality of magnetoresistance effect elements arranged along a first direction and a second direction which intersects the first direction; and an insulating layer including a plurality of hole portions provided for the plurality of magnetoresistance effect elements, respectively, wherein each of the plurality of magnetoresistance effect elements includes a first magnetic layer, a second magnetic layer provided on an upper layer side of the first magnetic layer, and a first non-magnetic layer provided between the first magnetic layer and the second magnetic layer, each of the second magnetic layer and the first non-magnetic layer included in each of the plurality of magnetoresistance effect elements includes a portion provided along a bottom surface and a side surface of a corresponding hole portion of the plurality of hole portions, and the portion of the second magnetic layer provided along the bottom surface and the side surface of the corresponding hole portion has magnetism, and at least a portion of the second magnetic layer, which is provided along the bottom surface of the corresponding hole portion has a variable magnetization direction.

Embodiments will now be described with reference to the accompanying drawings.

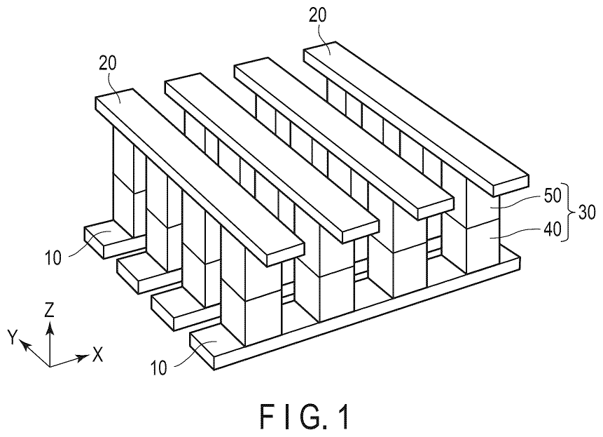

FIG. 1 is a perspective view schematically illustrating a basic configuration of a magnetic memory device according to the embodiment.

As shown in FIG. 1, the magnetic memory device of this embodiment includes a plurality of lower wiring lines 10 each extending along an X direction, a plurality of upper wiring lines 20 each extending in a Y direction, and a plurality of memory cells 30 each provided between a respective one of the lower wiring lines 10 and a respective one of the upper wiring lines 20.

The memory cells 30 are arranged along the X direction and the Y direction, and each of the memory cells 30 includes a magnetoresistance effect element 40 and a selector (switching element) 50 provided on an upper layer side of the magnetoresistance effect element 40, and includes a structure in which the magnetoresistance effect element 40 and the selector 50 are stacked in the Z direction. That is, the magnetoresistance effect elements 40 and the selectors 50 are arranged along the X direction and the Y direction.

Note that the X direction, Y direction, and Z direction are mutually intersecting directions. Specifically, the X direction, Y direction, and Z direction are orthogonal to each other.

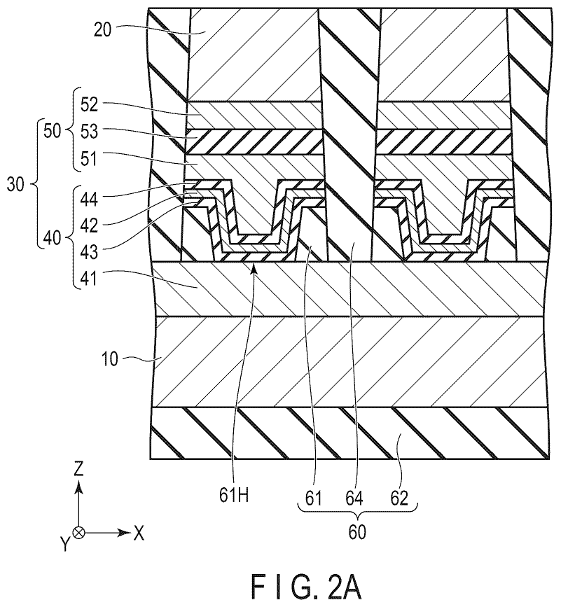

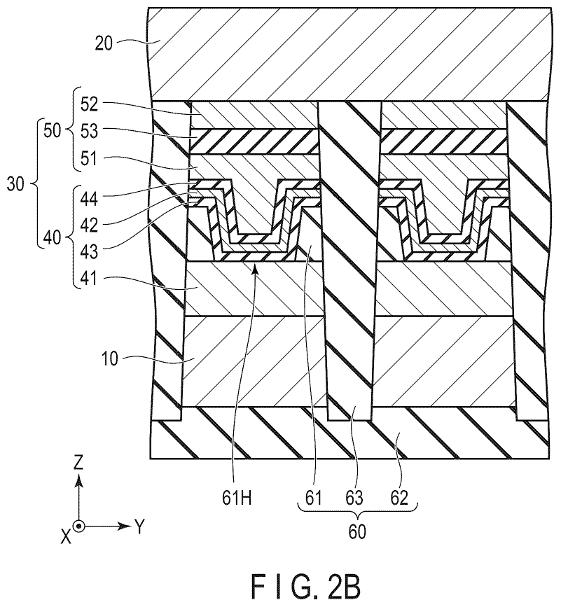

FIGS. 2A and 2B are cross-sectional views schematically illustrating a specific configuration of the magnetic memory device of this embodiment. FIG. 2A is a cross-sectional view taken along the X direction, and FIG. 2B is a cross-sectional view taken along the Y direction.

The magnetic memory device shown in FIGS. 2A and 2B is provided on an under region (not shown) including a semiconductor substrate (not shown) and the like, and includes a plurality of lower wiring lines 10, a plurality of upper wiring lines 20, a plurality of memory cells 30 each provided between the respective one of the lower wiring lines 10 and the respective one of the upper wiring lines 20, and an insulating region 60.

One of the groups of the lower wiring lines 10 and upper wiring lines 20 corresponds to word lines, and the other group of the lower wiring lines 10 and upper wiring lines 20 corresponds to bit lines. The lower wiring lines 10 and upper wiring lines 20 are formed from a metal material such as tungsten (W).

As already described, each of the plurality of memory cells 30 includes a magnetoresistance effect element 40 and a selector 50, and the magnetoresistance effect element 40 and the selector 50 are stacked along the Z direction.

The magnetoresistance effect element 40 is a magnetic tunnel junction (MTJ) element including a reference layer (first magnetic layer) 41, a storage layer (second magnetic layer) 42, a tunnel barrier layer (nonmagnetic layer) 43, and a cap layer (second nonmagnetic layer) 44.

The reference layer 41 is a ferromagnetic layer having a fixed magnetization direction, and is formed, for example, from a CoFeB layer containing cobalt (Co), iron (Fe), and boron (B), and a superlattice layer of platinum (Pt) and cobalt (Co). The term “fixed magnetization direction” means that the magnetization direction does not change for a predetermined write current.

The storage layer 42 is basically a ferromagnetic layer having a variable magnetization direction, and is formed, for example, from a CoFeB layer containing cobalt (Co), iron (Fe), and boron (B). The term “variable magnetization direction” means that the magnetization direction changes for a predetermined write current.

The tunnel barrier layer 43 is formed from an insulating material, is provided between the reference layer 41 and the storage layer 42, and is formed, for example, from an MgO layer containing magnesium (Mg) and oxygen (O).

The cap layer 44 is provided on an upper layer side of the storage layer 42, and is formed, for example, from an MgO layer containing magnesium (Mg) and oxygen (O). In the above description, although the tunnel barrier layer 43 is formed from an insulating material, exactly, the tunnel barrier layer 43 is a layer through which the tunnel current can be passed when the magnetic memory device performs memory operation.

When the magnetization direction of the storage layer 42 is parallel to the magnetization direction of the reference layer 41, the magnetoresistance effect element 40 exhibits a low-resistance state having relatively low resistance. When the magnetization direction of the storage layer 42 is antiparallel to the magnetization direction of the reference layer 41, the magnetoresistance effect element 40 exhibits a high-resistance state having relatively high resistance. With this configuration, the magnetoresistance effect element 40 can store binary data depending on the resistance state.

The magnetoresistance effect element 40 described above is a spin transfer torque (STT) type magnetoresistance effect element, and has perpendicular magnetization.

The selector 50 is a two-terminal switching element and includes a bottom electrode 51, a top electrode 52, and a selector material layer (switching material layer) 53 provided between the bottom electrode 51 and the top electrode 52. The selector 50 has the characteristic of changing from an off state to an on state when a voltage equal to or greater than a threshold voltage is applied between the bottom electrode 51 and the top electrode 52. Note that the bottom electrode 51 of selector 50 also functions as the top electrode for the magnetoresistance effect element 40.

The insulating region 60 includes insulating layers 61, 62, 63, and 64, which are used as interlayer insulating layers. These insulating layers 61, 62, 63, and 64 are formed, for example, of silicon oxide.

The insulating layer 61 includes a plurality of hole portions 61H, provided for the magnetoresistance effect elements 40, respectively. The insulating layer 62 is provided on the lower layer side of the lower wiring lines 10. The insulating layer 63 is provided in a plurality of trenches T1, which will be described later, and the insulating layer 64 is provided in a plurality of trenches T2, which will be described later. The insulating layer 62 is separated into a plurality of portions by the insulating layers 63 and 64, and a plurality of hole portions 61H are provided for the separated portions, respectively.

The storage layer 42, tunnel barrier layer 43, and cap layer 44 included in the magnetoresistance effect element 40 each includes a portion provided along the bottom surface and the side surface of the hole portion 61H and a portion provided on an outer side of the hole portion 61H.

The portion of the storage layer 42, provided along the bottom surface and the side surface of the hole portion 61H and the portion of the storage layer 42 provided on the outer side of the hole portion 61H have magnetism and are formed from the same magnetic material. Further, at least the portion of the storage layer 42, which is provided along the bottom surface of the hole portion 61H has a variable magnetization direction. It is preferable that the portion of the storage layer 42 provided along the side surface of the hole portion 61H and the portion provided on an outer side of the hole portion 61H as well have a variable magnetization direction.

The reference layer 41 extends continuously in the X direction. That is, the reference layer 41 included in one of a pair of magnetoresistance effect elements 40 that are adjacent along the X direction and the reference layer 41 included in the other of the pair of magnetoresistance effect elements 40 adjacent along the X direction are provided continuously in the X direction. The reference layer 41 is separated into parts along the Y direction. That is, the reference layer 41 included in one of the pair of the magnetoresistance effect elements 40 adjacent along the Y direction and the reference layer 41 included in the other one of the pair of the magnetoresistance effect elements 40 adjacent along the Y direction are spaced apart from each other along the Y direction.

Further, at least a part of the upper surface of the reference layer 41 corresponds to the bottom surface of the hole portion 61H. Therefore, the portion of the reference layer 41, which corresponds to the bottom surface of the hole portion 61H, and the portions of the storage layer 42 and the tunnel barrier layer 43, which are provided along the bottom surface of the hole portion 61H, form the substantial memory portion (operating portion) of the magnetoresistance effect element 40.

Therefore, at least the portion of the storage layer 42, which is provided along the bottom surface of the hole portion 61H need to have a variable magnetization direction. The portion of the storage layer 42, which is provided along the side surfaces of the hole portion 61H, and the portion provided on an outer side of the hole portion 61H do not have to have a variable magnetization direction. Note here that these portions are continuously provided from the portion provided along the bottom surface of the hole portion 61H. For this reason, it is preferable that the portion provided along the side surface of the hole portion 61H and the portion provided on the outer side of the hole portion 61H may have a variable magnetization direction so that the magnetization direction changes according to that of the portion provided along the bottom surface of the hole portion 61H.

Further, since the magnetoresistance effect element 40 has such a configuration as described above, the bottom electrode 51 of the selector 50 provided on the upper layer side of the magnetoresistance effect element 40 includes the portion provided in the hole portion 61H and the portion provided on the outer side of the hole portion 61H.

Furthermore, as will be described later, the pattern of the storage layer 42, tunnel barrier layer 43, and cap layer 44 of the magnetoresistance effect element 40 is formed in a common patterning process with the pattern of the selector 50. With this configuration, the side surfaces of the storage layer 42, tunnel barrier layer 43, and cap layer 44 are aligned with the side surface of the selector 50.

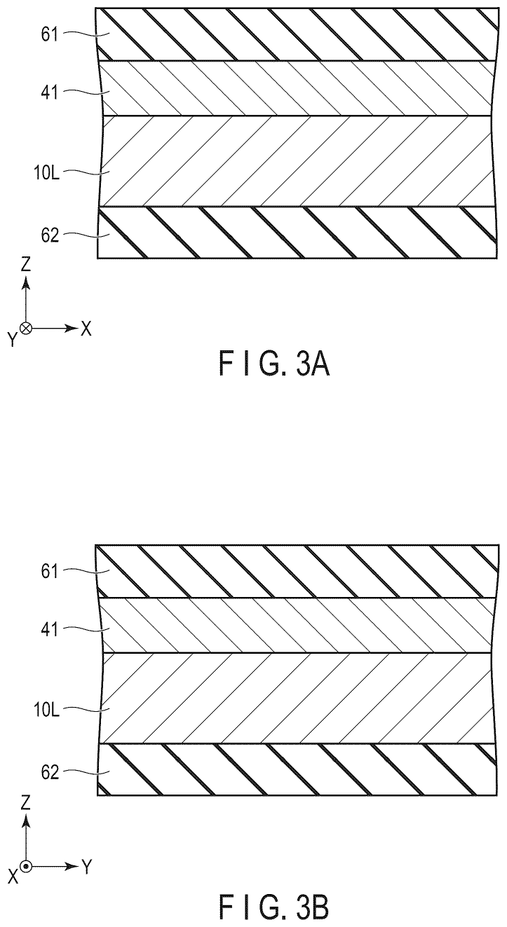

Next, a method of manufacturing the magnetic memory device according to this embodiment will be described with reference to FIGS. 3A and 3B to 13A and 13B. FIGS. 3A to 13A are cross-sectional views taken along the X direction, and FIGS. 3B to 13B are cross-sectional views taken along the Y direction.

First, as shown in FIGS. 3A and 3B, an insulating layer 62, a lower wiring layer 10L, a reference layer 41, and an insulating layer 61 are formed on an under region (not shown).

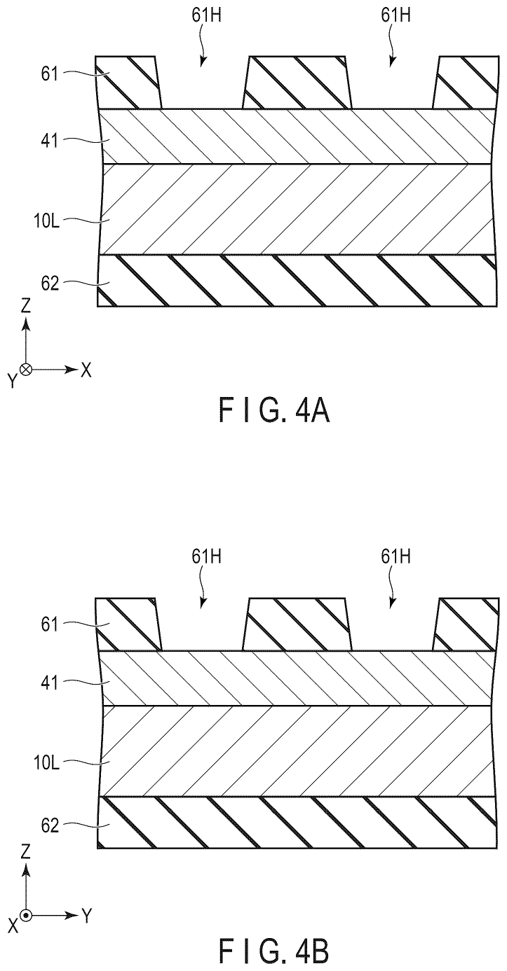

Next, as shown in FIGS. 4A and 4B, a plurality of hole portions (hole portions) 61H are formed in the insulating layer 61 so as to expose a part of the upper surface of the reference layer 41.

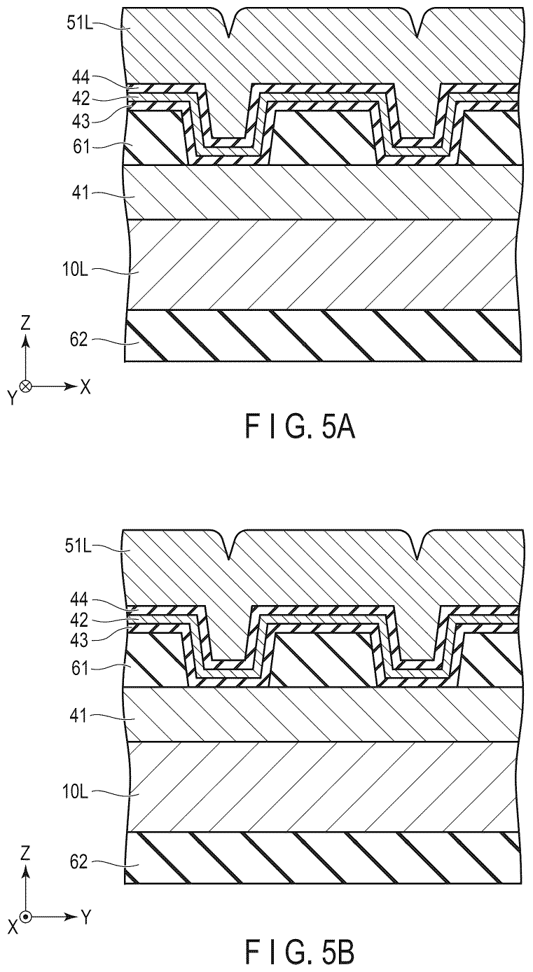

Then, as shown in FIGS. 5A and 5B, a tunnel barrier layer 43, a storage layer 42, a cap layer 44, and a bottom electrode layer 51L are formed on the configuration obtained in the step of FIGS. 4A and 4B, and the hole portions 61H are filled with these layers.

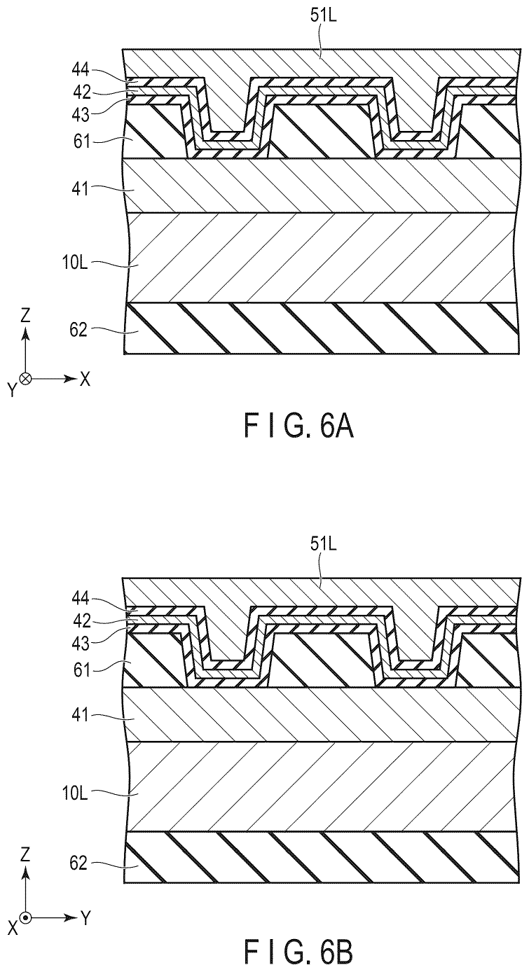

Subsequently, as shown in FIGS. 6A and 6B, the bottom electrode layer 51L is planarized by chemical mechanical polishing (CMP).

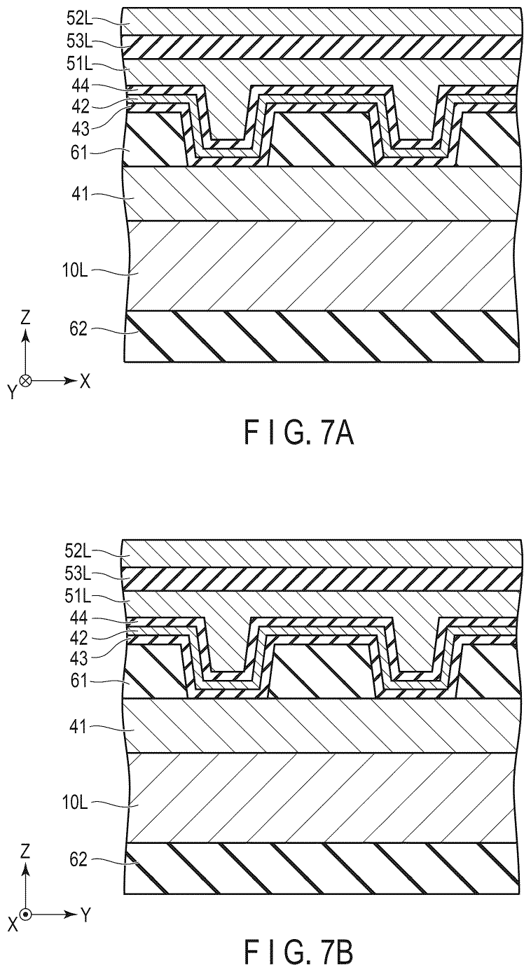

After that, as shown in FIGS. 7A and 7B, a selector material layer 53L and a top electrode layer 52L are formed on the planarized bottom electrode layer 51L.

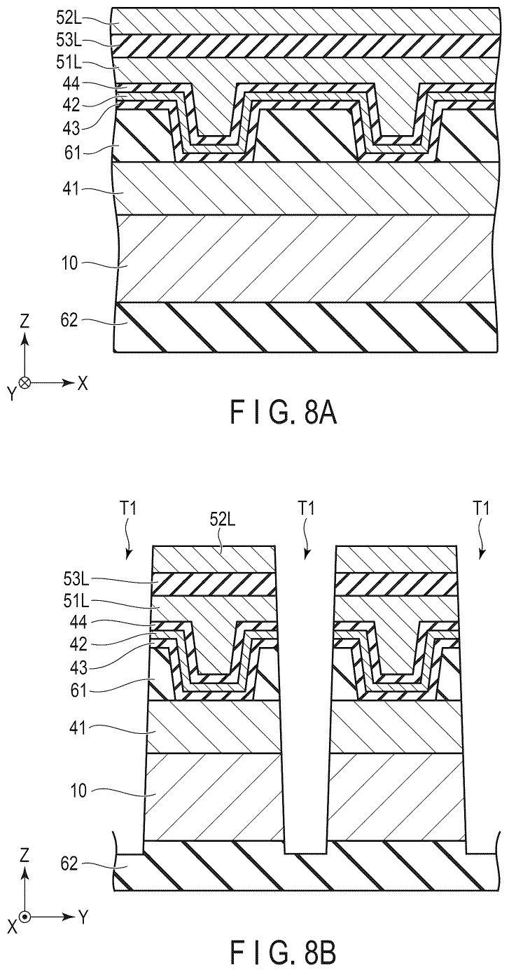

Next, as shown in FIGS. 8A and 8B, using a mask pattern having a plurality of line patterns as a mask, the lower wiring layer 10L, reference layer 41, storage layer 42, tunnel barrier layer 43, cap layer 44, bottom electrode layer 51L, top electrode layer 52L, selector material layer 53L, insulating layer 61, and insulating layer 62 are etched, and thus a plurality of trenches T1 are formed to extend along the X direction. Thus, the pattern of the lower wiring lines 10 and the reference layer 41 is formed.

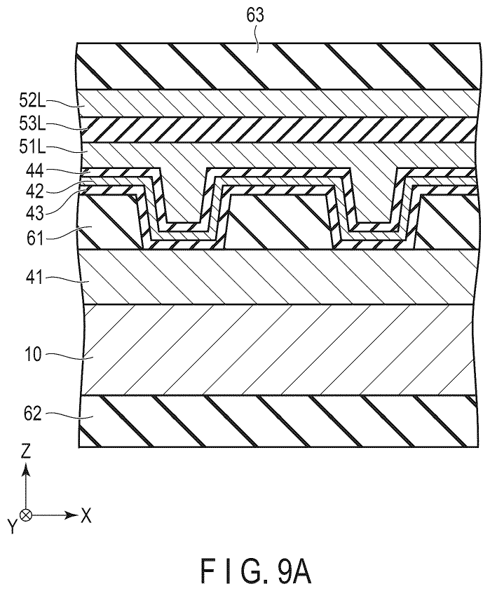

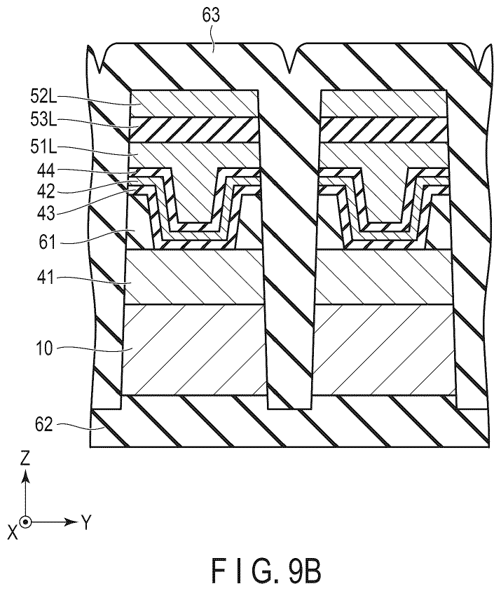

Then, as shown in FIGS. 9A and 9B, an insulating layer 63 is formed on the configuration obtained in the processing step of FIGS. 8A and 8B, and the trenches T1 are filled with the insulating layer 63.

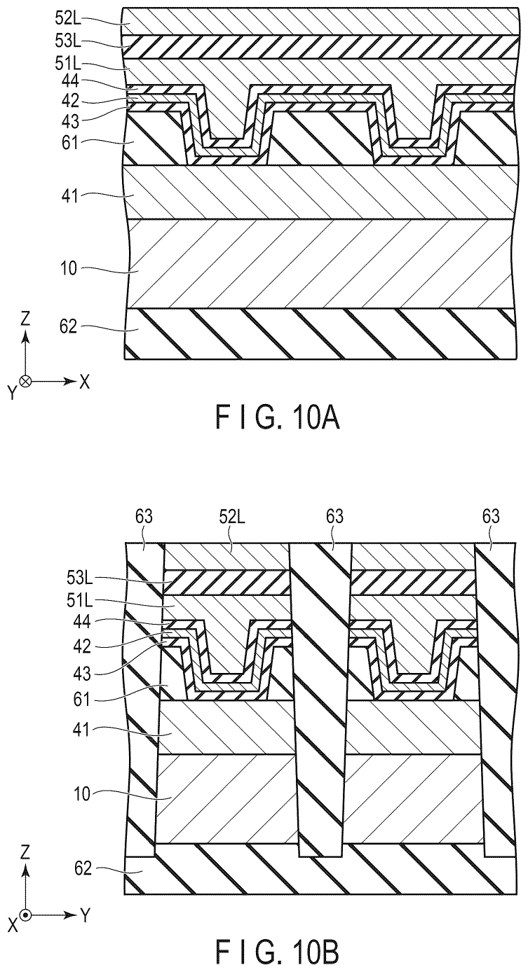

Subsequently, as shown in FIGS. 10A and 10B, the insulating layer 63 is planarized by CMP.

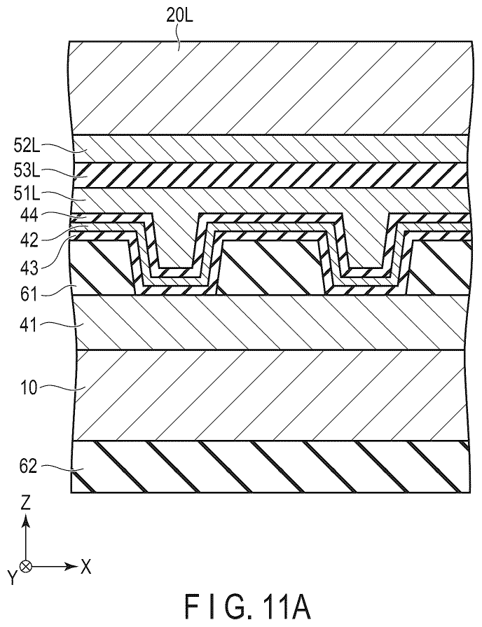

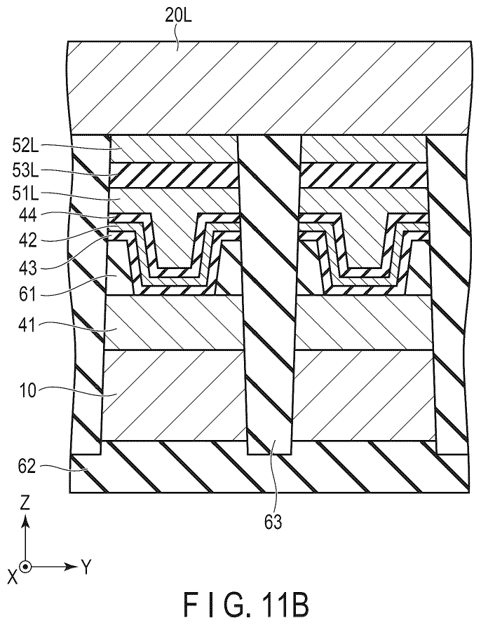

After that, as shown in FIGS. 11A and 11B, an upper wiring layer 20L is formed on the configuration obtained in the step of FIGS. 10A and 10B.

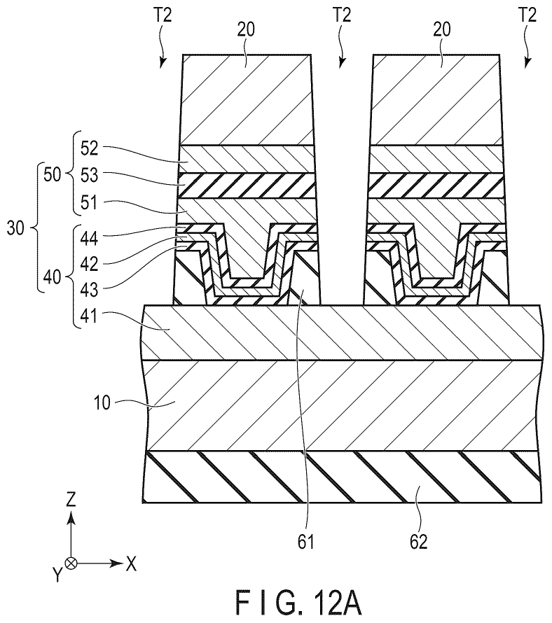

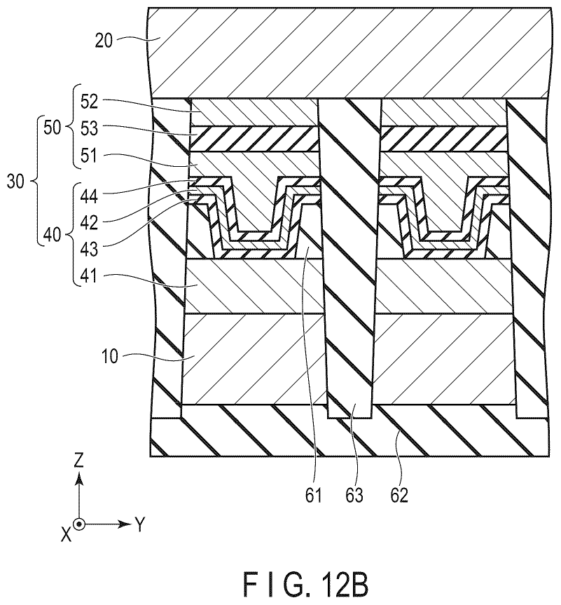

Next, as shown in FIGS. 12A and 12B, using a mask pattern having a plurality of line patterns as a mask, the upper wiring layer 20L, storage layer 42, tunnel barrier layer 43, cap layer 44, bottom electrode layer 51L, top electrode layer 52L, selector material layer 53L, and insulating layer 61 are etched, and thus a plurality of trenches T2 are formed to extend along the Y direction. Thus, the patterns of the upper wiring lines 20, magnetoresistance effect element 40, and selector 50 are formed.

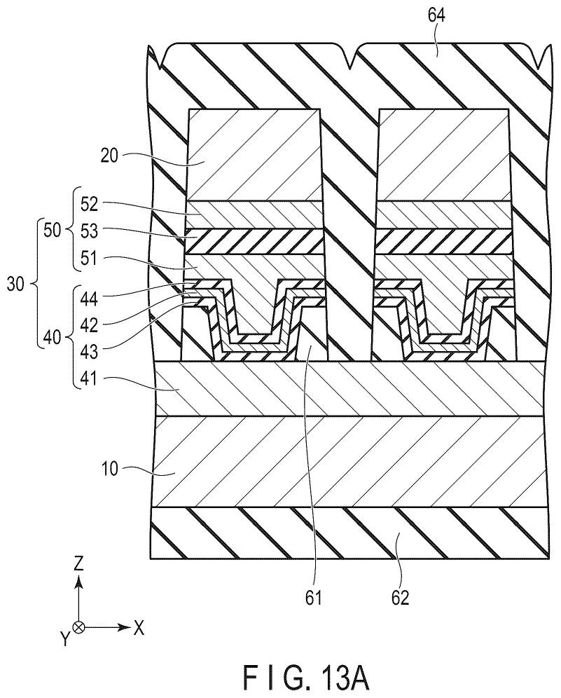

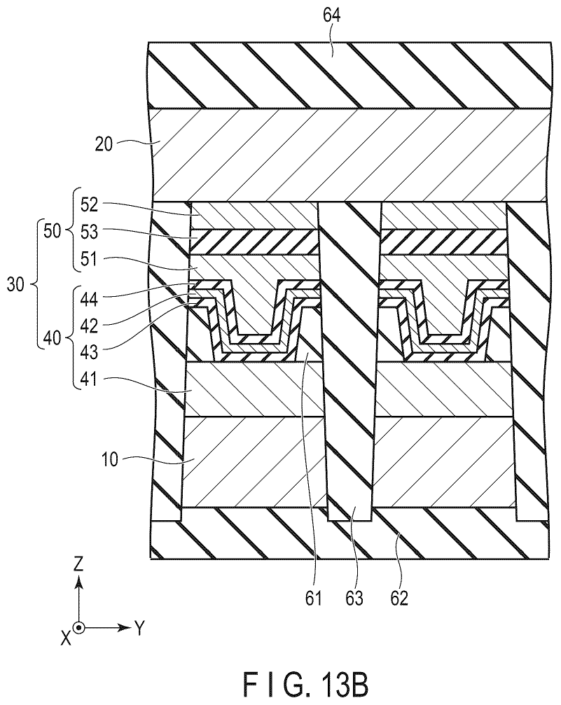

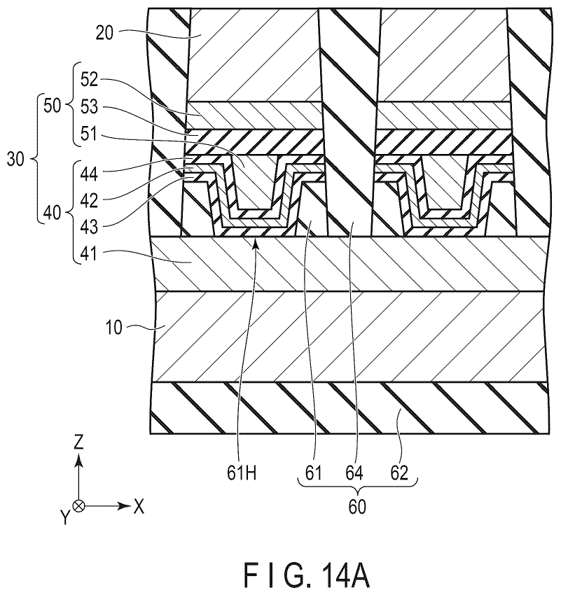

Then, as shown in FIGS. 13A and 13B, an insulating layer 64 is formed on the configuration obtained in the processing step of FIGS. 12A and 12B, and the trenches T2 are filled with the insulating layer 64.

After that, the insulating layer 64 is planarized by CMP, and thus such a configuration as shown in FIGS. 2A and 2B is obtained.

As described above, in this embodiment, the storage layer 42, tunnel barrier layer 43, and cap layer 44 are formed in the hole portions 61H. With this configuration, it is possible to obtain a magnetic memory device including a magnetoresistance effect element with excellent characteristics and reliability, as will now be described.

That is, generally, the pattern of a magnetoresistance effect element is formed by ion beam etching (IBE). Specifically, with use of a hard mask as a mask, an ion beam is applied from an oblique angle towards the magnetoresistance effect element layer while rotating the substrate, and thus the pattern of the magnetoresistance effect element is formed. When using IBE, it is required to use a hard mask having a certain thickness. Here, when the density of the magnetoresistance effect elements increases as the miniaturization of the magnetoresistance effect elements progresses, the ion beam is blocked by the hard mask, making it difficult to accurately form the pattern of the magnetoresistance effect element.

Further, when using IBE, the metal contained in the magnetoresistance effect element layer may redeposit on the side surface of the magnetoresistance effect element, causing shunt failure. Furthermore, the side surface of the magnetoresistance effect element may be damaged by IBE. Moreover, a problem such as the formation of high-resistance regions may occur due to oxidation process performed after IBE.

In this embodiment, a storage layer 42, a tunnel barrier layer 43, and a cap layer 44 are formed in each of the hole portion 61L. In this manner, from the portion of the reference layer 41 corresponding to the bottom surface of the hole portion 61H and the portions of the storage layer 42 and the tunnel barrier layer 43, which are provided along the bottom surface of the hole portion 61H, the substantial memory portion (substantial operating portion) of the magnetoresistance effect element 40 is formed. With this configuration, the substantial memory portion (substantial operating portion) of the magnetoresistance effect element 40 can be formed without using IBE.

Therefore, in this embodiment, such a problem as described above, caused by IBE can be avoided, and a magnetoresistance effect element having excellent characteristics and reliability can be obtained.

Further, in this embodiment, when the portion provided along the side surface of the hole portion 61H and the portion provided on the outer side of the hole portion 61H are configured such that their magnetization directions change in accordance with the magnetization direction of the portion provided along the bottom surface of the hole portion 61H, it is also possible to improve the retention characteristic of the magnetoresistance effect element 40.

Furthermore, in this embodiment, since the pattern of the magnetoresistance effect element 40 as viewed from the Z direction is rectangular, it is possible to increase the area of the magnetoresistance effect element 40 compared to when it is circular.

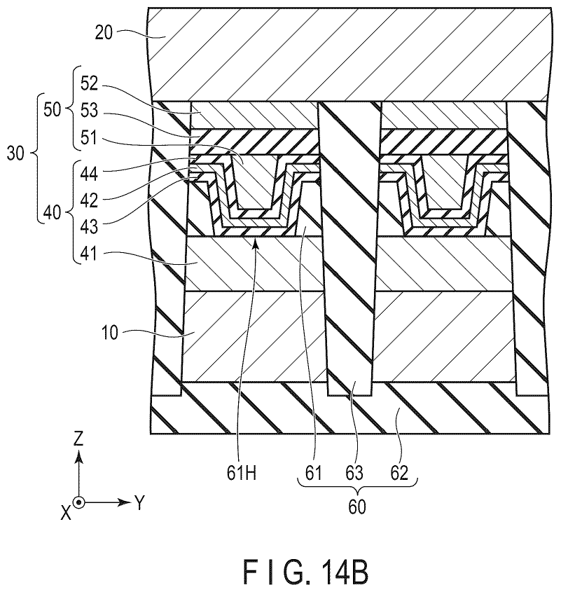

FIGS. 14A and 14B are cross-sectional views schematically illustrating a specific configuration of a magnetic memory device according to the first modified example of this embodiment. FIG. 14A is a cross-sectional view taken along the X direction, and FIG. 14B is a cross-sectional view taken along the Y direction.

As shown in FIGS. 14A and 14B, in this modified example, the bottom electrode 51 of the selector 50 is provided only in the hole portion 61H. The other basic configurations are similar to those described above. Therefore, advantageous effects similar to those described above can be obtained in this modified example as well.

Further, in this modified example, the area of the bottom electrode 51 of the selector 50 can be reduced by the above-described configuration, and therefore the current flowing to the memory cell 30 can be reduced when the selector 50 is in the off state.

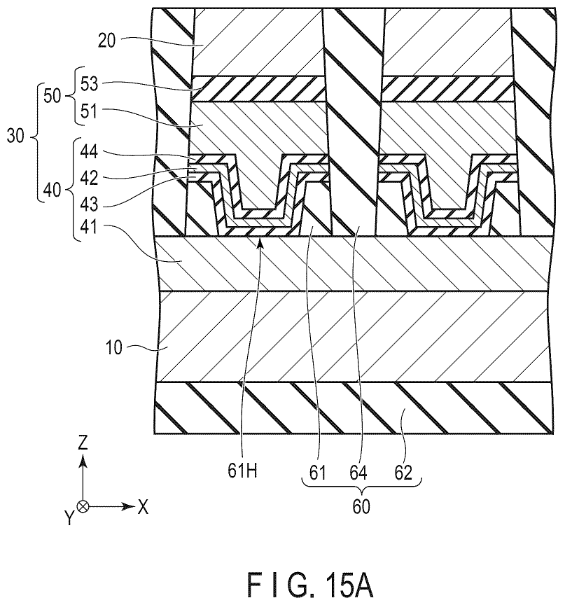

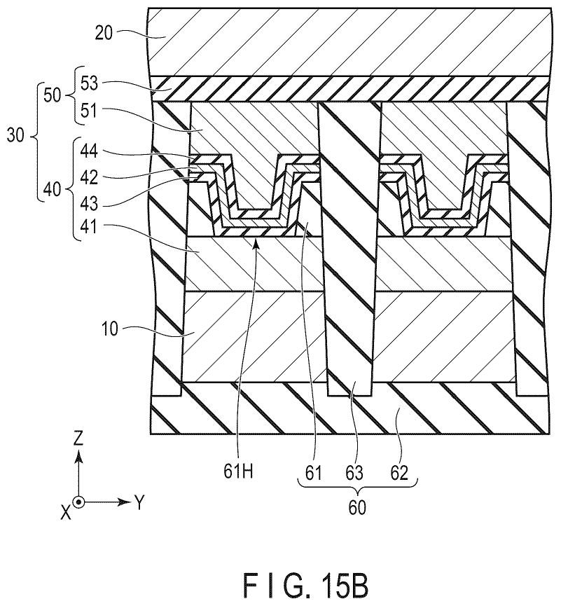

FIGS. 15A and 15B are cross-sectional views schematically illustrating a specific configuration of a magnetic memory device according to the second modified example of this embodiment. FIG. 15A is a cross-sectional view taken along the X direction, and FIG. 15B is a cross-sectional view taken along the Y direction.

As shown in FIGS. 15A and 15B, in this modified example, the selector material layer 53 included in one of the selectors 50 adjacent to each other along the Y direction and the selector material layer 53 included in the other one of the selectors 50 adjacent to each other along the Y direction are continuously provided in the Y direction. Further, in this modified example, the upper wiring line 20 are used as the top electrode of the selector 50 as well. The other basic configurations are similar to those described above. With such a configuration, advantageous effects similar to those described above can be obtained in this modified example as well.

Furthermore, in this modified example, the pattern of the upper wiring line 20 and the pattern of the selector material layer 53 can be formed in a common process, and therefore it is possible to reduce the degree of difficulty in processing.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is

1. A magnetic memory device comprising:
a plurality of magnetoresistance effect elements arranged along a first direction and a second direction which intersects the first direction; and
an insulating layer including a plurality of hole portions provided for the plurality of magnetoresistance effect elements, respectively,
wherein
each of the plurality of magnetoresistance effect elements includes a first magnetic layer, a second magnetic layer provided on an upper layer side of the first magnetic layer, and a first non-magnetic layer provided between the first magnetic layer and the second magnetic layer,
each of the second magnetic layer and the first non-magnetic layer included in each of the plurality of magnetoresistance effect elements includes a portion provided along a bottom surface and a side surface of a corresponding hole portion of the plurality of hole portions, and
the portion of the second magnetic layer provided along the bottom surface and the side surface of the corresponding hole portion has magnetism, and at least a portion of the second magnetic layer, which is provided along the bottom surface of the corresponding hole portion has a variable magnetization direction.

2. The device of claim 1, wherein
each of the second magnetic layer and the first non-magnetic layer included in each of the plurality of magnetoresistance effect elements further includes a portion provided on an outer side of the corresponding hole portion.

3. The device of claim 2, wherein
the portion of the second magnetic layer provided on the outer side of the corresponding hole portion has magnetism.

4. The device of claim 1, wherein
each of the plurality of magnetoresistance effect elements further includes a second non-magnetic layer provided on an upper layer side of the second magnetic layer, and
the second non-magnetic layer included in each of the plurality of magnetoresistance effect elements includes a portion provided along a bottom surface and a side surface of the corresponding hole portion.

5. The device of claim 4, wherein
the second non-magnetic layer included in each of the plurality of magnetoresistance effect elements further includes a portion provided on an outer side of the corresponding hole portion.

6. The device of claim 1, further comprising:
a plurality of electrodes provided on an upper layer side of the plurality of magnetoresistance effect elements, respectively,
wherein
each of the plurality of electrodes includes a portion provided in the corresponding hole portion.

7. The device of claim 6, wherein
each of the plurality of electrodes further includes a portion provided on an outer side of the corresponding hole portion.

8. The device of claim 6, wherein
each of the plurality of electrodes is provided only in the corresponding hole portion.

9. The device of claim 1, wherein
at least a portion of a top surface of the first magnetic layer included in each of the plurality of magnetoresistance effect elements corresponds to a bottom surface of the corresponding hole portion.

10. The device of claim 1, wherein
the first magnetic layer included in one of the magnetoresistance effect elements adjacent to each other along the first direction and the first magnetic layer included in the other of the magnetoresistance effect elements adjacent to each other along the first direction are continuously provided in the first direction.

11. The device of claim 10, wherein
the first magnetic layer included in one of the magnetoresistance effect elements adjacent to each other along the second direction and the first magnetic layer included in the other of the magnetoresistance effect elements adjacent to each other along the second direction are spaced apart from each other in the second direction.

12. The device of claim 1, further comprising:
a plurality of switching elements arranged along the first direction and the second direction and provided on an upper layer side of the plurality of magnetoresistance effect elements respectively.

13. The device of claim 12, wherein
side surfaces of the second magnetic layer and the first non-magnetic layer included in each of the plurality of magnetoresistance effect elements are aligned with a side surface of a corresponding switching element of the plurality of switching elements.

14. The device of claim 12, wherein
each of the plurality of switching elements includes a bottom electrode, a top electrode and a switching material layer provided between the bottom electrode and the top electrode, and
the switching material layer included in one of the switching elements adjacent to each other along the second direction and the switching material layer included in the other of the switching elements adjacent to each other along the second direction are continuously provided in the second direction.

15. The device of claim 12, wherein
the non-magnetic layer is a tunnel barrier layer.
